(19) United States
(12) Patent Application Publication
(10) Pub. No.: US 2004/0007710 A1
(43) Pub. Date: Jan. 15, 2004

(54) Novelty light assembly and method for making the same

(76) Inventors: Avery Joe Roy, Indianaolis, IN (US); Dawn Rene Sutton, Indianapolis, IN (US)

Correspondence Address: BARNES & THORNBURG, 11 SOUTH MERIDIAN, INDIANAPOLIS, IN, 46204

(21) Appl. No.: 10/194,350

(22) Filed: Jul. 12, 2002

(51) Int. Cl. H01L 33/00

(52) U.S. Cl. 257/88

(57) ABSTRACT

A novelty light assembly includes a transparent substrate, a light source embedded in the substrate and configured to emit light that propagates through the substrate, an object embedded in the substrate and configured to modify light propagating through the substrate, and a light control circuit embedded in the substrate and configured to control the light source. The circuit alters the wavelength and/or intensity of the each light source independently of the other light sources. A method of making the light assembly is also provided.

### FIELD OF THE DISCLOSURE

The present disclosure relates generally to the field of novelty light assemblies.

### BACKGROUND OF THE DISCLOSURE

Novelty devices are popular decorative items for homes, lawns and gardens, cars, and offices. One type of novelty device is a novelty light assembly. A novelty light assembly may be operated to produce a variety of different light schemes. For example, a novelty light assembly may produce varying color or visual schemes. Examples of novelty light assemblies include colored incandescent lamps and “lava” lamps.

### SUMMARY OF THE DISCLOSURE

According to one exemplary aspect of the disclosure, there is provided a novelty light assembly having a transparent substrate, a plurality of light sources embedded in the substrate, an object or objects embedded in the substrate and configured to modify the light propagating through the substrate, and a light control circuit embedded in the substrate and configured to control the light sources. The light control circuit alters the wavelength and/or intensity of the each light source independently of the other light sources. The wavelength and/or intensity of the light sources may be altered in response to external input such as a sound pulse, a light wave, an ambient temperature, or a user-controlled device. The embedded object or objects could be, for example, a ribbon, a geometric piece of plastic, a void of substrate, dye, or air bubbles.

### BRIEF DESCRIPTION OF THE DRAWINGS

The detailed description particularly refers to the accompanying figures in which:

FIG. 1 is a diagrammatic view of a novelty light assembly having a light source and objects embedded in a substrate;

FIG. 2 is a view similar to FIG. 1, but showing another embodiment of a novelty light assembly in which objects are placed around the light source;

FIG. 3 is a view similar to FIG. 1, but showing a novelty light assembly having a number of different types of objects embedded in the substrate;

FIG. 4 is a view similar to FIG. 1, but showing a novelty light assembly in which the substrate is embodied as a material which hardens sufficiently such that a container is not needed to hold the substrate; and

FIG. 5 is a view similar to FIG. 1, but showing a novelty light assembly in which the light control circuit for controlling the light source is positioned outside of the substrate.

### DETAILED DESCRIPTION OF THE DRAWINGS

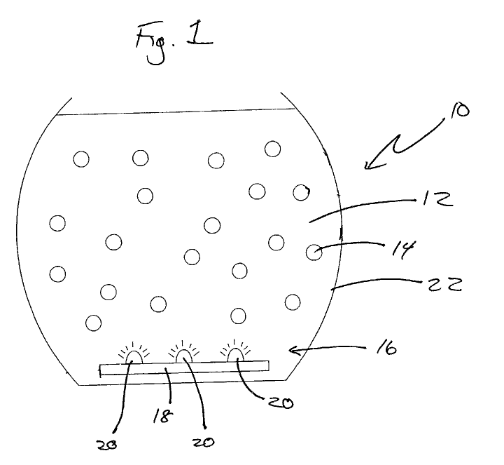

As shown in FIG. 1, a novelty light assembly 10 illustratively has a transparent substrate 12 housed within a transparent container 22, a number of objects 14 embedded in the substrate 12, and a light source 16 embedded in the substrate 12. Illustratively, light source 16 is embodied as three light emitting diodes (LEDs) 20 configured to emit selected colors of light. However, it should be understood that other means of emitting light are within the scope of the disclosure.

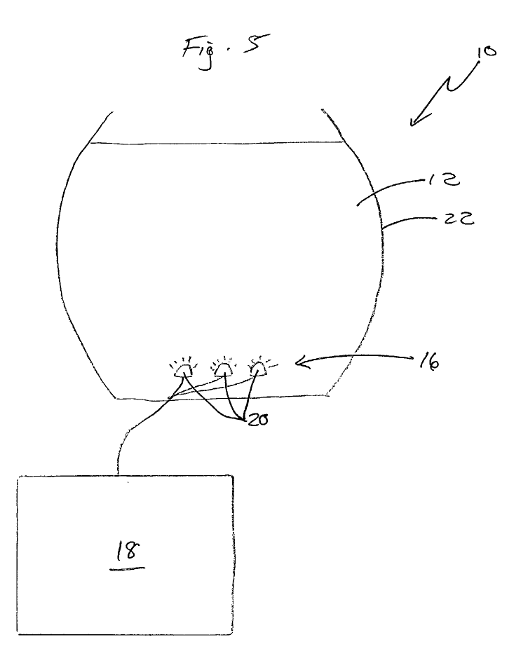

A light control circuit 18 is also illustratively embedded in substrate 12. Circuit 18 illustratively alters the wavelength and/or intensity of each of LEDs 20 of light source 16 independently of the other LEDs 20. Although circuit 18 is shown embedded in substrate 12, it is within the scope of the disclosure to have circuit 18 remote from substrate 12 such that circuit 18 is electrically coupled to light source 16, as shown diagrammatically in FIG. 5.

Substrate 12 can be composed of any material which allows for light to be propagated through substrate 12 and out of assembly 10. Substrate 12 is illustratively transparent or semi-transparent. For example, substrate 12 may be a polyester resin, an acrylic, a shredded transparent film or foil, a transparent potting or casting fluid, plastic, glass, ceramic, gel, candle wax, liquids such as oil or water-based mixtures, organic fluids, air, steam, or fog. Substrate 12 may be a single solid material, gel or liquid material, or particles of solid material. Substrate 12 is illustratively housed in a transparent container 22, however, it is within the scope of the disclosure to utilize a substrate that does not require a container 22 to contain it or keep its shape. It is also within the scope of the disclosure to form the substrate 12 from multiple layers of material, or any other desired configuration.

Object 14 is illustratively any material or structure that modifies light originating from light source 16 and propagating or passing through assembly 10. As used herein, the terms “modify”, “modifies”, or “modified” are intended to mean any reflection, refraction, absorption, dispersion, or other type of alteration of the light generated by light source 16. As such, object 14 may illustratively be a film, foil, ribbon, geometric article of any composition, a portion of the substrate having dye, or even a void of substrate 12 such as an air bubble. Illustratively, a plurality of objects 14 is used together in order to create additional visual effects, however, it is within the scope of the disclosure to utilize only one embedded object 14 to create a desired visual effect.

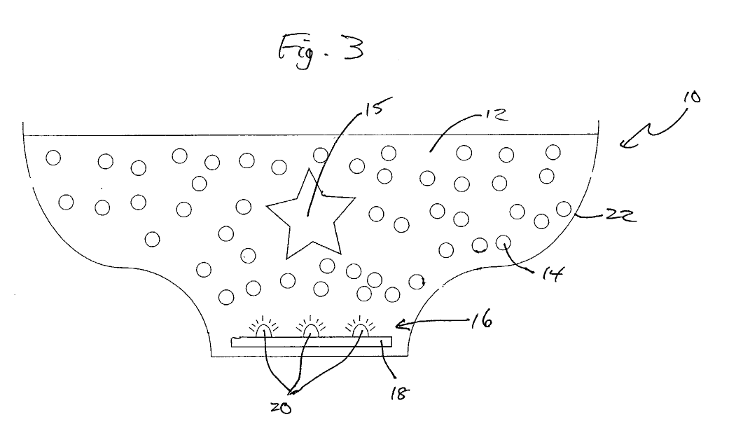

It is also within the scope of the disclosure to use a variety of embedded objects. An example of two different types of embedded objects can be seen in FIG. 3. Illustratively, a plurality of objects 14 may be dispersed throughout substrate 12, some of which may be varied in size, geometry, color, composition, or in any other way. An example of an object that is varied is referenced by the number 15. Such a varied object 15 illustratively provides a varied visual effect. Embodiments for objects 14, 15 are discussed in more detail below.

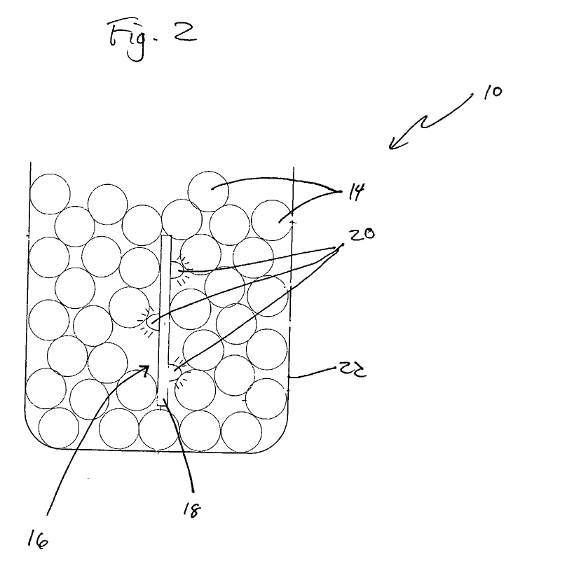

Another embodiment of assembly 10 is shown in FIG. 2, in which light source 16 is positioned between objects 14 held by container 22. In such an embodiment, a substrate material 12 is unnecessary. Assembly 10 provides visual effects by directing light toward and/or through objects 14, which modify the light as it passes through assembly 10. It should be understood that although objects 14 appear to be uniform in the illustrative drawing, it is possible to utilize any variety of objects 14.

Yet another embodiment is shown in FIG. 3, in which a plurality of objects 14 is embedded in substrate 12, and at least one varied object 15 is also embedded in substrate 12. Light control circuit 18 may control light source 16 to create certain optical effects. For example, the light source 16 may be operated such that objects 14 or 15 appear to disappear and thereafter reappear. These optical effects may be achieved by, for example, manipulating the intensity and/or wavelength (color) of light emitted by light source 16 such that object 14 or object 15 appears to blend in or disappear in the substrate 12. Illustratively, object 15 may be colored and a wavelength propagated through substrate 12 that passes unmodified through object 15, causing object 15 to appear diminished. It should be understood that while other embodiments discussed in the present disclosure do not illustrate a varied object 15 embedded in the substrate 12, it is within the scope of the disclosure to provide such an arrangement.

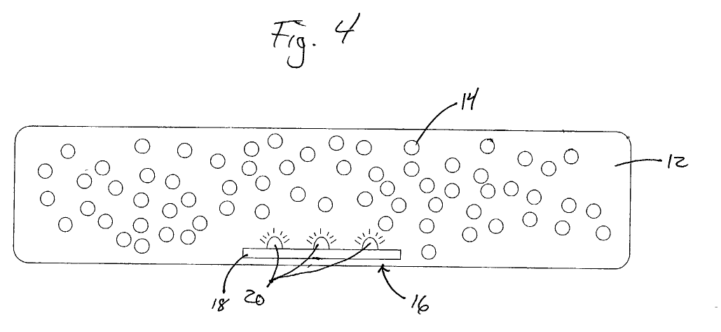

FIG. 4 shows yet another embodiment in which substrate 12 is formed from a material with physical properties that allow it to serve as its own container. Illustratively, substrate 12 in FIG. 4 is a thick gel with embedded objects 14 such as bubbles or particles.

In yet another embodiment (not shown), a container 22 could be configured to completely enclose substrate 12. Such an embodiment would allow for substrate 12 to be embodied as a material in the gaseous or liquid state. For example, substrate 12 could be embodied as an oil- or water-based mixture, organic fluids, or air. Alternatively, container 22 could include ports through which steam or fog could be piped. The ports could direct substrate 12 in such a way that turbulent substrate flow is achieved, thereby adding yet more variety to the visual effects achievable by assembly 10.

Although each illustrative embodiment described thus far shows a full kit with assembly 10, it is within the scope of the disclosure to provide for only portions of the kit. For example, a user could provide the substrate or objects to be embedded while only the circuit 18 and light source 16 would need to be separately acquired. Alternatively, the substrate, objects to be embedded, circuit, and light source may be provided as a kit for assembly by the user into a container of the user's choice. Other user-provided combinations are likewise within the scope of the disclosure.

In each of the illustrated embodiments, circuit 18 cooperates with light source 16 in substantially the following fashion. Circuit 18 controls light source 16 to emit light in either a random or orderly fashion. A selector (not shown) can be coupled to circuit 18 for user-controlled selection of the manner in which light is emitted. Additionally, circuit 18 could be configured to sense external input in the form of vibrations, sound, music, light, ambient temperature of the surroundings, a remote control, or any other type of external input. Circuit 18 can be configured to cooperate with light source 16 such that any embedded objects 14, 15 are made to look as if they are moving or as if they disappear or diminish.

Illustratively, light source 16 is embodied as three LEDs emitting the additive primary colors; however, it is within the scope of the disclosure to provide alternative numbers of LEDs, as well as to provide other means of emitting light. For example, laser diodes, filtered light bulbs, and other light-emitting sources are contemplated by this disclosure. Each LED or other light-emitting source is illustratively individually controlled by circuit 18. Therefore, each LED or light-emitting source can be controlled as to intensity and/or wavelength of the emitted light. By controlling each LED individually, complex patterns and thousands of colors can be produced by the substrate-embedded LEDs. Because of the transparent characteristics of substrate 12, animated projected light can be seen on surrounding surfaces such as walls, floors, and ceilings.

It should be appreciated that although specific exemplary embodiments have been illustrated and described herein, other embodiments which are not specifically illustrated or described herein are within the spirit and scope of the disclosure. For example, substrate 12 could be embodied as a candle wax or gel having a wick disposed therein. Moreover, substrate 12 could be embodied as a fragrance-emitting gel. Container 22 may likewise be embodied as a number of different structures which are not specifically illustrated or described herein. For example, container 22 may be embodied as a flower vase, a night light or ornamental lamp, or a Christmas ornament.

Still other embodiments could incorporate completely non-related colors (with respect to full-spectrum emission), such as in the case of an illuminated storm globe or a pumpkin-shaped container. A storm globe could be embodied as a container in which objects resembling a landscape are embedded in the substrate 12. It is conceived that a blue light source would be used to illuminate embedded objects which appear to be rain falling and a white light source could be used to flash bold lightening strikes via an embedded optical pipe shaped object. In the case of a pumpkin-shaped container, an orange and yellow light source could be utilized to emulate the essence of a burning candle in a jack-o-lantern.

As described herein, light source 16 is illustratively a non-incandescent source of light (e.g., LED's), thereby emitting little or negligible amounts of heat during operation. This is advantageous since the generation of excessive heat would allow for the use of only a limited number of substrates 12 due to potential melting of the substrate.

As shown in FIG. 5, circuit 18 may be positioned outside of substrate 12 and is electrically coupled to light source 16. This embodiment may be advantageous for certain light assembly designs.

It is contemplated by this disclosure that multiple novelty light assemblies 10 may be synchronized with one another via electrical, optical, or other communications link. This would permit the combined visual effects achieved by a plurality of assemblies 10. It is further contemplated that circuit 18 and light source 16 may be battery-operated, or may be powered by electricity via a standard 110V AC outlet.

A method of making a novelty light assembly 10 is also contemplated by the present disclosure. The method includes the steps of positioning light source 16 and light control circuit 18 in container 22. Thereafter, substrate 12 is advanced into container 22 thereby embedding light source 16 and light control circuit 18 therein. A number of objects 14 may then be embedded in the substrate while the substrate 12 is in a liquid or gel form. It should be appreciated that, if desired, light source 16 and/or light control circuit 18 may be embedded in substrate 12 after introduction of substrate 12 into container 22.

While the disclosure is susceptible to various modifications and alternative forms, specific exemplary embodiments thereof have been shown by way of example in the drawings and have herein been described in detail. It should be understood, however, that there is no intent to limit the disclosure to the particular forms disclosed, but on the contrary, the intention is to cover all modifications, equivalents, and alternatives falling within the spirit and scope of the invention as defined by the appended claims.

There is a plurality of advantages of the present disclosure arising from the various features of the novelty light assembly and associated method described herein. It will be noted that alternative embodiments of the novelty light assembly and associated method of the present disclosure may not include all of the features described yet still benefit from at least some of the advantages of such features. Those of ordinary skill in the art may readily devise their own implementations of a novelty light assembly and associated method that incorporate one or more of the features of the present disclosure and fall within the spirit and scope of the present disclosure as defined by the appended claims.

1. A novelty light assembly comprising:
a transparent substrate,
a plurality of light sources embedded in the substrate, the plurality of light sources being configured to emit light into the substrate such that light propagates through the substrate,
an object embedded in the substrate, the object being configured to modify the light propagating through the substrate, and
a light control circuit embedded in the substrate and configured to control the plurality of light sources by altering the wavelength and/or intensity of each one of the plurality of light sources independently of the other light sources.

2. The assembly of claim 1, wherein the circuit alters the wavelength and/or intensity of the light sources in response to an external input.

3. The assembly of claim 2, wherein the external input is at least one selected from the group comprising a sound pulse, a light wave, an ambient temperature, and a user-controlled device.

4. The assembly of claim 1, wherein the object includes at least one selected from the group comprising a ribbon, a geometric piece of plastic, a void of substrate, dye, and an air bubble.

5. The assembly of claim 1, wherein the circuit and light source cooperate to selectively illuminate and diminish the appearance of the embedded object.

6. The assembly of claim 1, wherein the plurality of light sources comprises light emitting diodes.

7. A novelty light assembly comprising:
a transparent substrate,
a light source embedded in the substrate, the light source being configured to emit light into the substrate such that light propagates through the substrate,
an object embedded in the substrate, the object being configured to modify the light propagating through the substrate, and
a light control circuit electrically coupled to the light source and configured to alter the wavelength and/or intensity of the light source thereby altering the appearance of the embedded object.

8. The assembly of claim 7, wherein a plurality of objects is embedded in the substrate.

9. The assembly of claim 8, wherein the plurality of objects includes at least one selected from the group comprising ribbons, geometric pieces of plastic, voids of substrate, dyes, and air bubbles.

10. The assembly of claim 7, wherein at least one of the wavelengths emitted by the light source causes the appearance of the embedded object to diminish.

11. The assembly of claim 7, further comprising a container into which the substrate is poured while in the liquid state.

12. The assembly of claim 7, wherein the light source comprises three light emitting diodes.

13. The assembly of claim 7, wherein the light control circuit controls light characteristics including beam divergence, direction, wavelength, and intensity.

14. The assembly of claim 7, wherein the light control circuit alters the wavelength and/or intensity of the light source in response to external input.

15. The assembly of claim 7, wherein the external input is at least one selected from the group comprising a sound pulse, a light wave, an ambient temperature, and a user-controlled device.

16. A novelty light assembly comprising:
a transparent substrate,
an object embedded in the substrate,
a light source embedded in the substrate, and
a light control circuit electrically coupled to the light source and configured to alter the wavelength and/or intensity of the light source in response to external input.

17. The assembly of claim 16, wherein the external input is at least one selected from the group comprising a sound pulse, a light wave, an ambient temperature, and a user controlled device.

18. The assembly of claim 16, wherein a plurality of objects is embedded in the substrate.

19. The assembly of claim 18, wherein the plurality of objects includes at least one selected from the group comprising ribbons, geometric pieces of plastic, voids of substrate, dyes, and air bubbles.

20. The assembly of claim 16, wherein at least one of the wavelengths emitted by the light source causes the appearance of the embedded object to diminish.

21. The assembly of claim 16, further comprising a container into which the substrate is poured while in the liquid state.

22. The assembly of claim 16, wherein the light source comprises three light emitting diodes.

23. The assembly of claim 16, wherein the circuit and light source cooperate to control light characteristics including beam divergence, direction, wavelength, and intensity.

24. A method of making a novelty light assembly comprising the steps of:
positioning a light source in a container,
positioning a light control circuit in the container, the light control circuit being configured to alter the wavelength and/or intensity of the light source,
advancing a substrate into the container so as to embed both the light source and the light control circuit therein, and
embedding an object in the substrate while the substrate is in a liquid or gel form.

25. The method of claim 24, wherein the substrate comprises at least one selected from the group comprising polyester resin, acrylic, shredded transparent film, shredded transparent foil, transparent potting, transparent casting fluid which hardens, plastic, glass, ceramic, gel, candle wax, fragrance gel, solids which expand and become liquid-saturated gels when exposed to moisture, liquids, oils, water or water-based mixtures, various organic fluids, gas, air—including steam and steam-based fogs, and non-steam based fogs.

26. The method of claim 24, wherein the substrate comprises at least one selected from the group comprising polyester resin, plastic, gel, and acrylic.

27. The method of claim 24, wherein the light source is non-incandescent.
